(19) United States
(12) Patent Application Publication
(10) Pub. No.: US 2017/0294747 A1
(43) Pub. Date: Oct. 12, 2017

(54) RADIO COMMUNICATION FILTERING APPARATUS AND RADIO CONTROL APPARATUS

(71) Applicant: FUJITSU LIMITED, Kawasaki-shi (JP)

(72) Inventors: Takuma Narishige, Kawasaki (JP); Kenichi KUDO, Yokohama (JP)

(73) Assignee: FUJITSU LIMITED, Kawasaki-shi (JP)

(21) Appl. No.: 15/437,030

(22) Filed: Feb. 20, 2017

(30) Foreign Application Priority Data
Apr. 7, 2016 (JP) 2016-077349

(51) Int. Cl. H01P 1/20; H01R 13/74; H03H 1/00

(52) U.S. Cl. CPC H01R 13/748; H01R 13/74; H01R 13/746; H03H 1/0007; H03H 2001/0021

(57) ABSTRACT

A radio communication filtering apparatus includes: a filter main body including a connector attaching portion and a grooved portion that encloses at least a part of the connector attaching portion; and a connector to be attached to the connector attaching portion.

### CROSS-REFERENCE TO RELATED APPLICATION

This application is based upon and claims the benefit of priority of the prior Japanese Patent Application No. 2016-077349, filed on Apr. 7, 2016, the entire contents of which are incorporated herein by reference.

### FIELD

The embodiments discussed herein are related to a radio communication filtering apparatus and a radio control apparatus.

### BACKGROUND

There is a structure for reducing occurrence of passive inter modulation (PIM) in semi-coaxial cavity resonators.

Related art is disclosed in International Publication Pamphlet No. WO 2006/073027.

### SUMMARY

According to an aspect of the embodiments, a radio communication filtering apparatus includes: a filter main body including a connector attaching portion and a grooved portion that encloses at least a part of the connector attaching portion; and a connector to be attached to the connector attaching portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a radio base station according to a first embodiment;

FIG. 2 is a diagram illustrating an example of a perspective view of a radio communication filtering apparatus;

FIG. 3 is a diagram illustrating an example of a perspective view of a filter main body of the radio communication filtering apparatus;

FIG. 4 is a diagram illustrating an example of a cross-sectional view taken along line IV-IV illustrated in FIG. 3;

FIG. 5 is a diagram illustrating a cross-sectional view taken along line V-V illustrated in FIG. 2;

FIG. 6 is a diagram illustrating an example of a plan view of the internal configuration of the radio communication filtering apparatus;

FIG. 7 is a diagram illustrating an example of a side view of the internal configuration of the radio communication filtering apparatus;

FIG. 8 is a diagram illustrating an example of a method for mounting the radio communication filtering apparatus to an apparatus casing;

FIG. 9 is a diagram illustrating an example of a cross-sectional view of a fixed portion of the apparatus casing and a connector;

FIG. 10 is a diagram illustrating an example of the generation source of passive inter modulation (PIM);

FIGS. 11A and 11B are diagrams illustrating a comparative example of mounting of a radio communication filtering apparatus;

FIGS. 12A and 12B are diagrams illustrating an example of mounting of the radio communication filtering apparatus;

FIG. 13 is a diagram illustrating an example of the apparatus casing to which the connector is attached;

FIG. 14 is a diagram illustrating an example of the shape of a grooved portion;

FIG. 15 is a diagram illustrating an example of the shape of a grooved portion;

FIG. 16 is a diagram illustrating an example of the shape of a grooved portion; and

FIG. 17 is a diagram illustrating a filter main body and a connector according to a second embodiment.

### DESCRIPTION OF EMBODIMENTS

For example, passive inter modulation occurs when local nonlinear changes in voltage and current occur, resulting from contact, such as connection of different kinds of metal or poor contact of connectors. Since radio communication filtering apparatuses are constituted of many components, and therefore have many points of metal contact, it may be difficult to effectively reduce passive inter modulation.

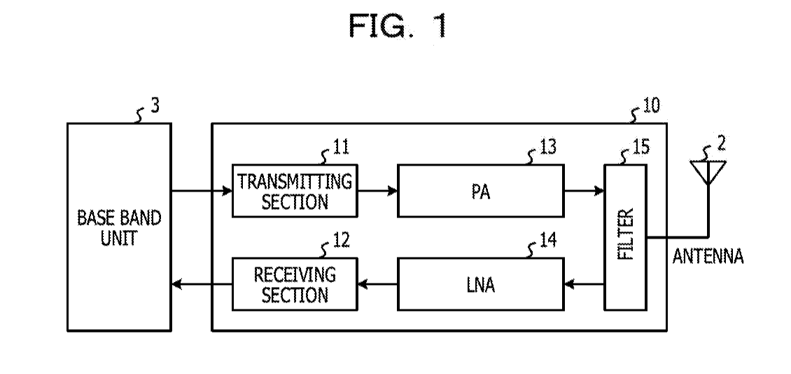

FIG. 1 illustrates a radio base station according to a first embodiment.

As illustrated in FIG. 1, a radio base station 10 (an example of a radio control apparatus) is disposed between an antenna 2 and a base band unit (BBU) 3. For example, the radio base station 10 and the base band unit 3 may be connected via an optical cable.

The radio base station 10 includes a transmitting section 11, a receiving section 12, a power amplifier (PA) 13, a low-noise amplifier (LNA) 14, and a filter 15.

The transmitting section 11 and the receiving section 12 convert signals and transmit and reception frequencies. The power amplifier 13 amplifies radio frequency (RF) signals to predetermined output power. The low-noise amplifier 14 amplifies feeble radio waves received by the antenna 2. The filter 15 cuts unwanted waves generated through a transmission path and unwanted waves transmitted in the atmosphere and permits only a desired frequency to pass through. In receiving signals, radio waves received by the antenna 2 are transmitted to the receiving section 12 via the filter 15 and the low-noise amplifier 14. In transmitting signals, RF signals from the transmitting section 11 are transmitted to the antenna 2 via the power amplifier 13 and the filter 15.

Although the filter 15 in FIG. 1 is a transmitting and receiving filter (a duplexer), any other filters may be used. The filter 15 may be separately provided for reception and transmission.

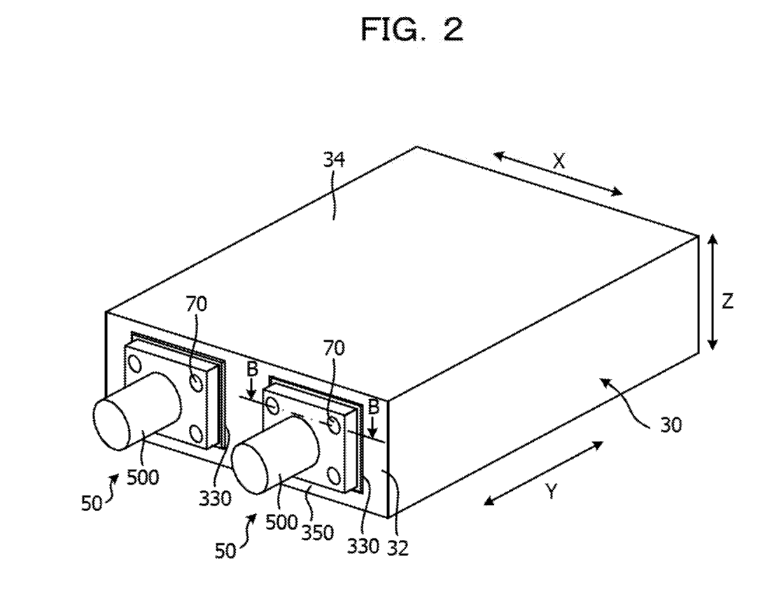

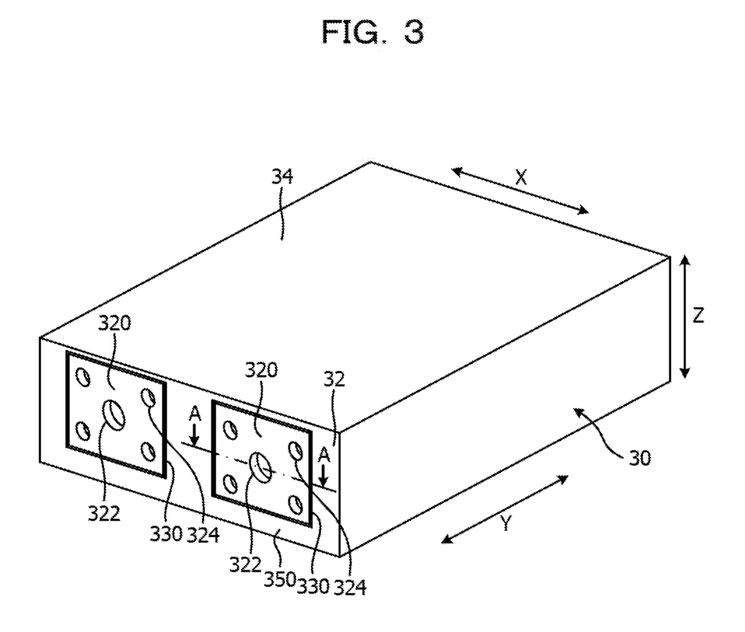

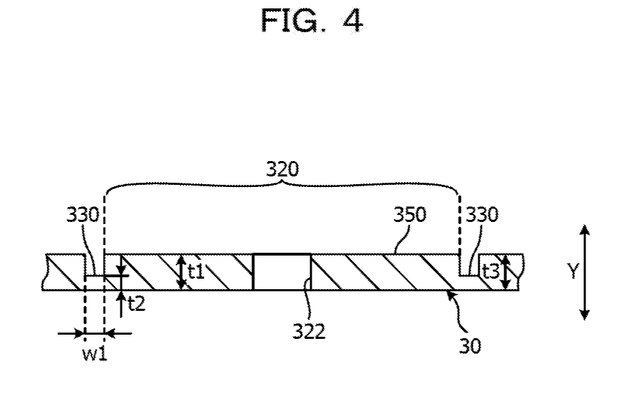

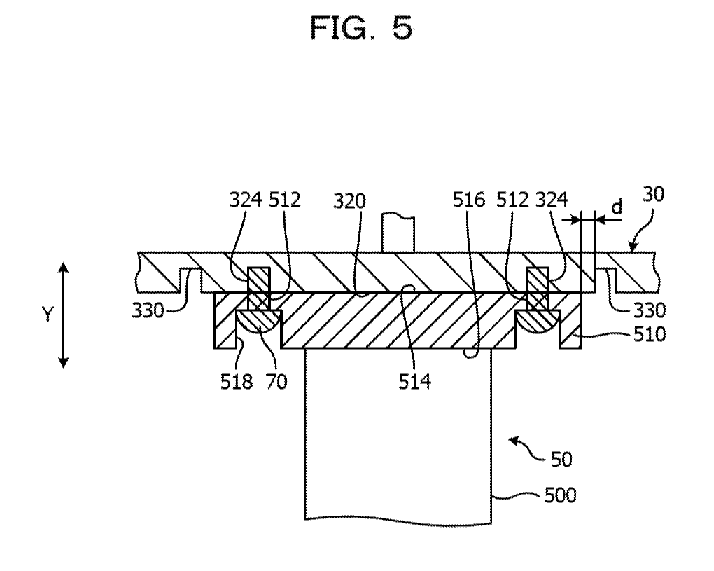

FIG. 2 illustrates an example of a perspective view of a radio communication filtering apparatus. FIG. 3 illustrates an example of a perspective view of the filter main body of the radio communication filtering apparatus. FIG. 4 illustrates an example of a cross-sectional view taken along line IV-IV in FIG. 3. FIG. 5 illustrates an example of a cross-sectional view taken along line V-V in FIG. 2. In FIG. 2, three directions perpendicular to one another, that is, X-direction, Y-direction, and Z-direction, are defined. The dispositions of individual members may be described as appropriate hereinbelow using the X-direction, Y-direction, and Z-direction illustrated in FIG. 2. For illustrative purpose, the X-direction is a lateral direction, the Y-direction is a front-to-back direction, and the Z-direction is a vertical direction.

The radio communication filtering apparatus 1 may be used as the filter 15 of the radio base station 10 illustrated in FIG. 1.

The radio communication filtering apparatus 1 includes a filter main body 30 and a connector 50. For example, the radio communication filtering apparatus 1 may include two connectors 50 to form a duplexer having two systems. The number of connectors 50 (for example, the number of systems) may be any number, that is, one or three or more.

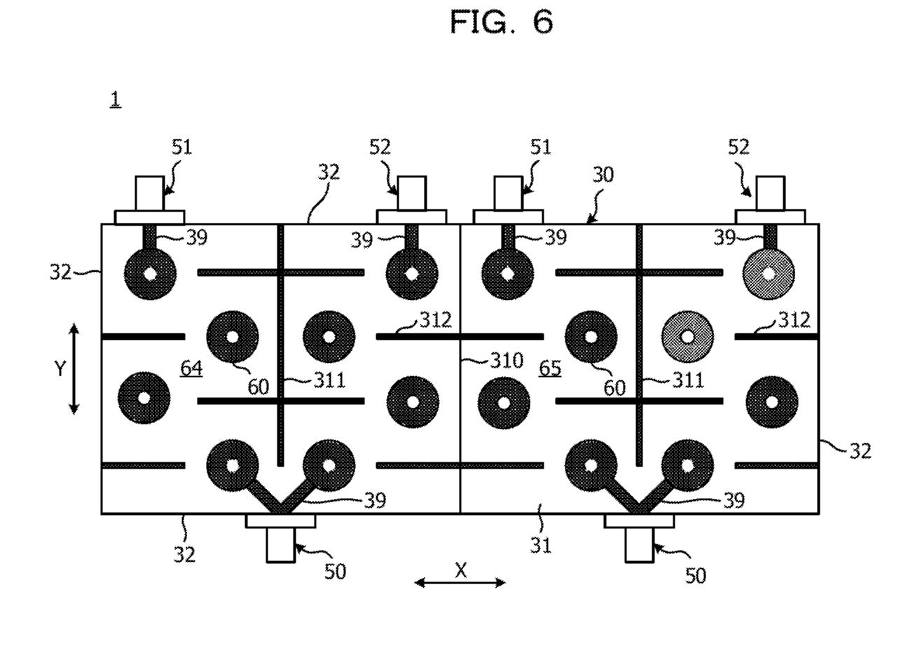

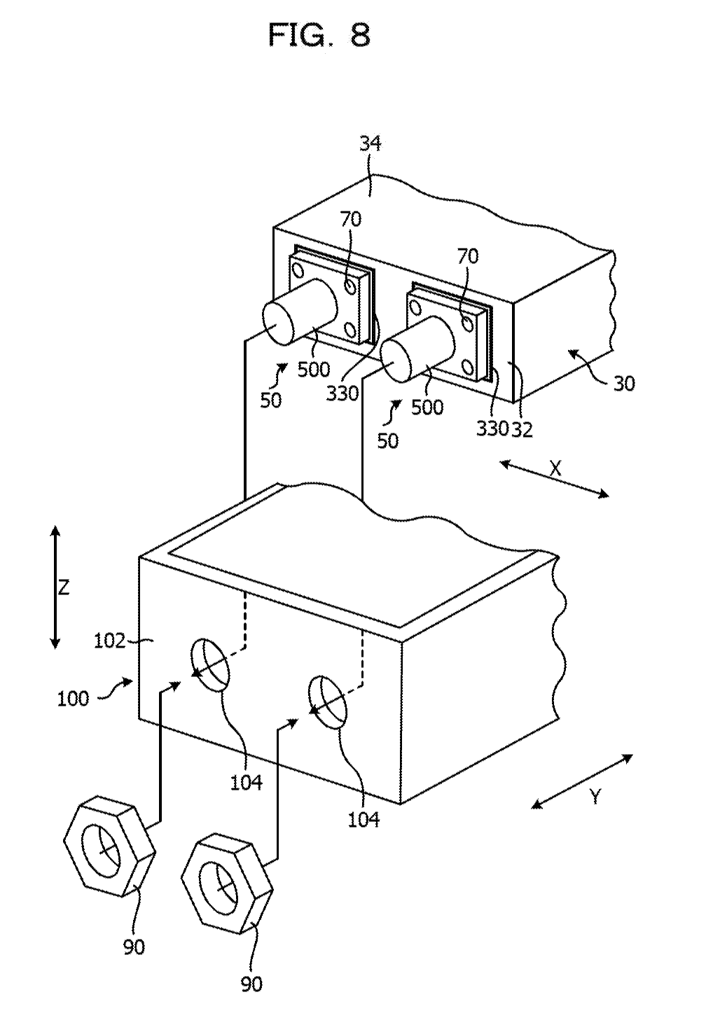

The filter main body 30 may be made of, for example, aluminum or brass. For example, the filter main body 30 may be a die-cast aluminum product. The filter main body 30 may be a substantially rectangular parallelepiped, or a casing having a space therein. For example, the filter main body 30 includes a substantially rectangular bottom 31 (see FIG. 6) and side walls 32 on the four sides of the bottom 31. The top of the filter main body 30 is open, on which a filter cover 34 serving as a lid is provided. An outer surface of the filter main body 30 hereinafter refers to a surface viewed from the outside (≠near the inner space covered by the filter cover 34). The filter main body 30 is electrically connected to a ground potential. For example, the filter main body 30 is electrically connected to the ground potential via an apparatus casing 100 (see FIG. 8).

The filter main body 30 includes connector attaching portions 320 (see FIG. 3) and grooved portions 330. As illustrated in FIGS. 2 and 3, if a plurality of connectors 50 are to be attached, the connector attaching portion 320 and the grooved portion 330 are provided for each connector 50. The filter main body 30 includes the connector attaching portions 320 and the grooved portions 330 at a front side wall 32.

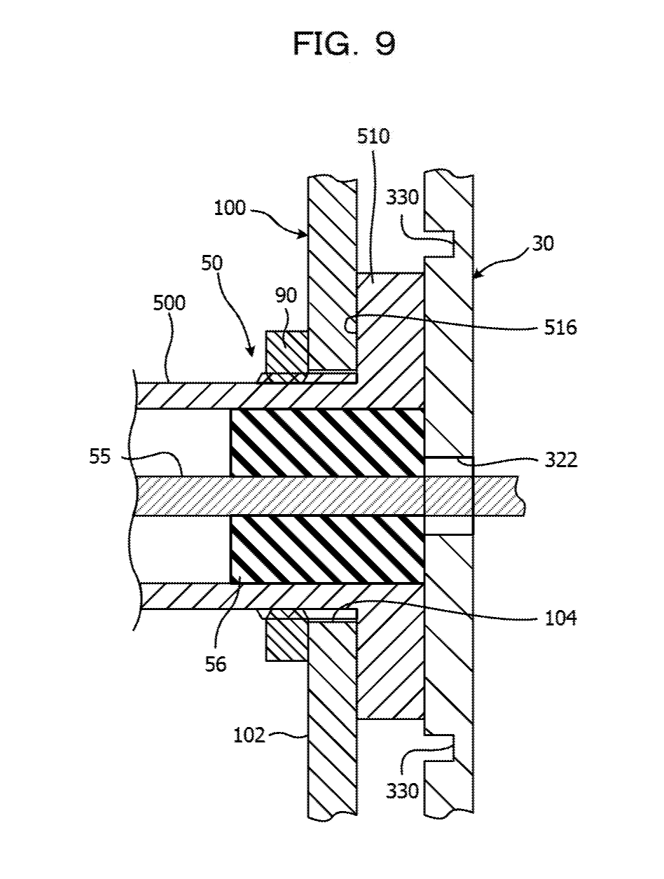

The connector attaching portions 320 are used to attach the connectors 50, as illustrated in FIG. 2. Each connector attaching portion 320 has a through hole 322 through which a pin (probe) 55 (see FIG. 9) through the connector 50 is to be passed. The connector attaching portion 320 also has screw holes 324 to which connector fastening screws 70 are to be fastened. The screw holes 324 may not pass through the connector attaching portion 320.

The grooved portions 330 each enclose the connector attaching portion 320, as illustrated in FIG. 3. For example, the grooved portions 330 are each provided around the outer periphery of each connector attaching portion 320. The grooved portions 330 are provided in the outer surface of the filter main body 30. The grooved portions 330 have the function of partitioning a peripheral portion 350 and the connector attaching portion 320 and changing the position of the connector attaching portion 320 relative to the peripheral portion 350 by deforming the partition.

As illustrated in FIG. 4, the plate thickness t2 of the grooved portion 330 is smaller than the maximum plate thickness t1 of the connector attaching portion 320. The “maximum” plate thickness t1 of the connector attaching portion 320 is the plate thickness of a region of the connector attaching portion 320 excluding the region of the screw holes 324. This may be hereafter simply referred to as “plate thickness t1 of the connector attaching portion 320”. For example, the plate thickness t1 of the connector attaching portion 320 may be uniform and may be substantially equal to the basic plate thickness t3 of the peripheral portion 350. For example, the plate thickness t1 of the connector attaching portion 320 may be slightly larger than the basic plate thickness t3 of the peripheral portion 350. The “basic” plate thickness t3 of the peripheral portion 350 indicates the plate thickness of the major part of the peripheral portion 350, excluding the plate thickness of an uneven region that can be formed in the peripheral portion 350. The plate thicknesses t1 and t2 and the width w1 of the grooved portion 330 will be described later.

The connector 50 is used to connect the radio base station 10 and the antenna 2 illustrated in FIG. 1. The connector 50 includes the pin 55, an insulator 56, etc. (see FIG. 9). One end (a free end) of the pin 55 is electrically connected o the antenna 2 to electrically connect the radio base station 10 and the antenna 2 together. The other end of the pin 55 forms a probe 39 (see FIG. 6). The main body 500 of the connector 50 is formed of, for example, stainless steel, such as SUS 303, or brass. The insulator 56 electrically insulates the main body 500 and the pin 55 from each other.

The connector 50 is of a bulkhead type attached to the connector attaching portion 320 of the filter main body 30. This may reduce the use of a cable in a type in which a connector is attached to the apparatus casing 100 (described later) (a cable between the apparatus casing 100 and the filter main body 30), decreasing passage loss. As illustrated in FIG. 2, the outer periphery of the connector 50 is enclosed by the grooved portion 330 when attached to the filter main body 30.

For example, as illustrated in FIGS. 2 and 5, the connector 50 includes a connector flange 510 at an end of the cylindrical main body 500. The connector 50 is fixed to the filter main body 30 with connector fastening screws 70 that pass through holes 512 in the connector flange 510 (see FIG. 5). The connector flange 510 has a flat surface 516 opposite to an attaching surface 514. The connector flange 510 has recesses 518 recessed from the surface 516, for example, at the four corners of the rectangle, and has the holes 512 in the individual recesses 518. The depth of the recesses 518 from the surface 516 (the depth in the Y-direction) may be set larger than the height of the heads of the connector fastening screws 70. This may reduce exposure of the heads of the connector fastening screws 70 from the surface 516. The connector flange 510 is in contact with the outer surface of the filter main body 30, with the connector 50 attached to the filter main body 30. For example, the attaching surface 514 of the connector flange 510 is joined to the outer surface of the connector attaching portion 320. The connector flange 510 is electrically connected to the ground potential via the filter main body 30.

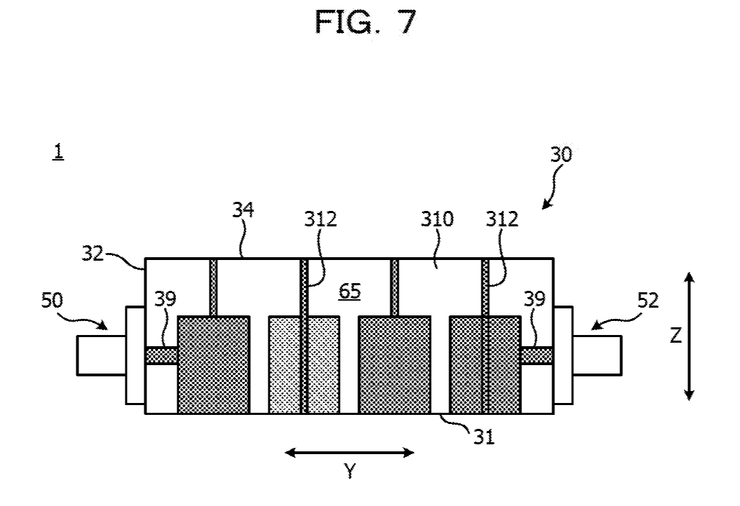

FIG. 6 illustrates an example of a plan view of the internal configuration of the radio communication filtering apparatus 1. FIG. 7 illustrates an example of a side view of the internal configuration of the radio communication filtering apparatus 1. In FIG. 6, the filter cover 34 at the top is omitted to allow the internal configuration to be viewed. Likewise, in FIG. 7, the side wall 32 at the right is omitted to allow the internal configuration to be viewed.

In FIGS. 6 and 7, for example, the radio communication filtering apparatus 1 includes two connectors 50 and two sets of connectors 51 and 52 for the two systems—the transmitting system and the receiving system—at opposite ends in the front-to-back direction. The connectors 51 and 52 are used to connect to the power amplifier 13 and the low-noise amplifier 14 of the radio base station 10 illustrated in FIG. 1. Instead of the connectors 51 and 52, another connection method, for example, connection using a cable, may be applied.

In FIGS. 6 and 7, the filter main body 30 has, at the bottom 31, a partition wall 310 that partitions the inner space of the filter main body 30 into spaces 64 and 65. The spaces 64 and 65 each include a partition wall 311 that separates the transmitting system and the receiving system from each other and include a plurality of resonators 60 in staggered form. The spaces 64 and 65 each have walls 312 extending in the lateral direction. Each wall 312 is disposed before and behind each resonator 60. The resonators 60 and the connectors 50, 51, and 52 are connected via the probes 39. For example, the probes 39 extending from the connectors 50, 51, and 52 are each connected to the resonator 60 by soldering or the like.

FIG. 8 illustrates an example of a method for mounting the radio communication filtering apparatus 1 to the apparatus casing 100. FIG. 8 illustrates the apparatus casing 100 in which the components of the radio base station 10 (see FIG. 1) are housed.

The radio base station 10 includes the apparatus casing 100 that houses the radio communication filtering apparatus 1 and so on. The apparatus casing 100 has an internal space capable of housing the radio communication filtering apparatus 1 and other components (the components of the radio base station 10). The top of the apparatus casing 100 is open in FIG. 8 but is covered with a cover or the like (not illustrated) in the product state of the radio base station 10.

The apparatus casing 100 has through holes 104 in a side wall 102 at the front. In the radio communication filtering apparatus 1, the connectors 50 are exposed to the outside of the apparatus casing 100 through the through holes 104. Nuts (an example of fasteners) 90 are fastened to the connectors 50, for example, exposed portions thereof, outside the apparatus casing 100. For example, the main body 500 of each connector 50 has an external thread around the outer circumference thereof, to which the nut 90 is fastened. This causes the apparatus casing 100 and the connectors 50 are fastened together with the nuts 90, so that the radio communication filtering apparatus 1 is secured to the apparatus casing 100. For fastening the connectors 50, anti-loosening washers may be used in addition to the nuts 90.

FIG. 9 illustrates an example of a cross-sectional view of a fixed part between the apparatus casing 100 and the connector 50. As illustrated in FIG. 9, when the connector 50 is fixed to the apparatus casing 100 of the radio communication filtering apparatus 1, the surface 516 (the surface opposite to the attaching surface 514) of the connector flange 510 comes into contact with the inner surface (a surface near the internal space) of the side wall 102 of the apparatus casing 100. The surface (fastening surface) of the side wall 102 of the apparatus casing 100 with which the surface 516 of the connector flange 510 comes into contact may be hereinafter referred to as “a contact surface of the apparatus casing 100”.

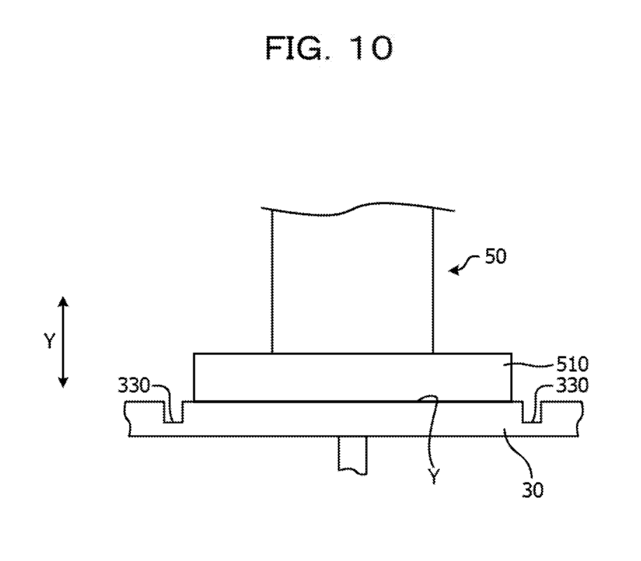

FIG. 10 illustrates an example of the generation source of passive inter modulation (PIM). FIG. 10 illustrates a contact portion between the connector flange 510 and the filter main body 30. For example, FIG. 10 illustrates the relationship between the connector flange 510 and the filter main body 30 not in cross sectional view.

The passive inter modulation may occur due to contact, such as contact between different kinds of metal or poor contact of the connector. In the radio communication filtering apparatus 1, for example, the contact portion between the connector flange 510 and the filter main body 30 (see thick line Y) has an influence on the passive inter modulation. To reduce passive inter modulation due to the contact portion, the physical contact between the connector flange 510 and the filter main body 30 may be stably maintained and thus stabilize electrical connection to the ground. For example, the physical surface contact between the attaching surface 514 of the connector flange 510 and the outer surface of the connector attaching portion 320 of the filter main body 30 may be stably maintained.

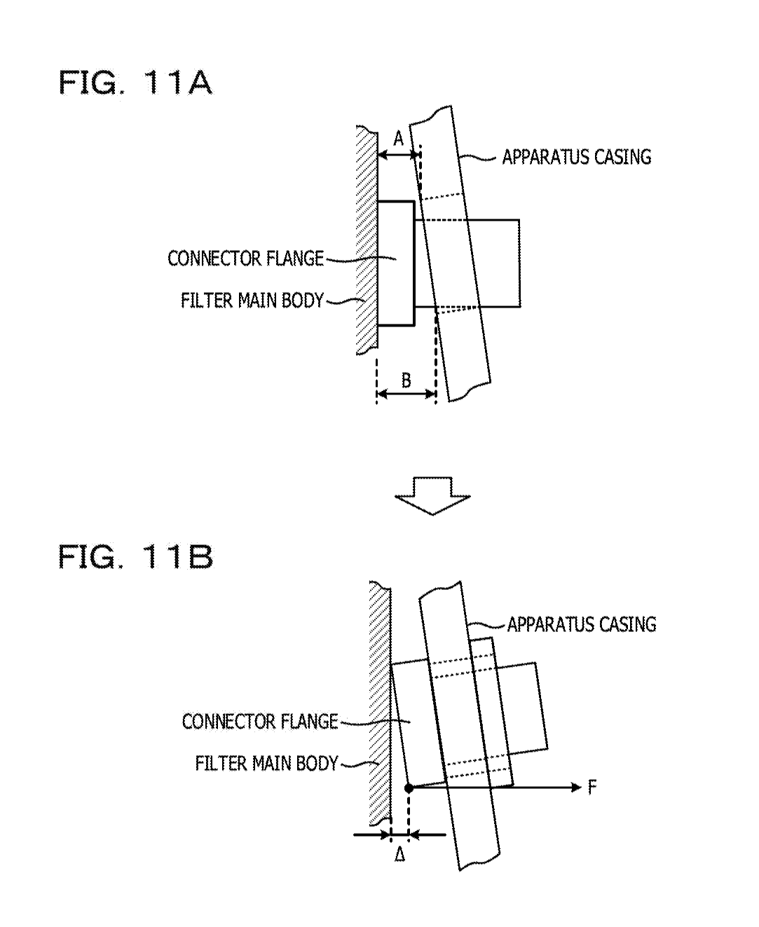

FIGS. 11A and 11B illustrate a comparative example of mounting of a radio communication filtering apparatus. The radio communication filtering apparatus illustrated in FIGS. 11A and 11B differs from the radio communication filtering apparatus 1 illustrated in FIG. 2 in that the grooved portions 330 are not provided and may be the same in the other configuration. A region of the outer surface of the side wall 32 at the front of the filter main body 30 in which the connector attaching portion 320 is disposed, for example, the region enclosed by the grooved portion 330, may be referred to as “connector attaching surface”. For example, the connector attaching surface refers to the outer surface of the connector attaching portion 320.

FIGS. 11A and 11B illustrate attachment when the contact surface of the apparatus casing and the connector attaching surface of the filter main body, or the surface of the connector flange (hereinafter typified by “connector attaching surface”), are not parallel to each other. For example, in FIGS. 11A and 11B, for a dimension (distance) A and a dimension (distance) B between the connector attaching surface of the filter main body and the contact surface of the apparatus casing, the dimension A is significantly smaller than the dimension B depending on the position of the surface of the connector flange. Thus, for example, a state in which the connector attaching surface and the contact surface of the apparatus casing is not parallel to each other is conceivable. This refers to a state in which two surfaces that are desirably parallel are not parallel. Dimensional difference caused by the fact that the connector attaching surface and the contact surface of the apparatus casing are not parallel may be hereinafter referred to as “dimensional difference (B−A)”. A direction passing through the center of the connector attaching surface and in which the dimensional difference (B−A) is the maximum may be referred to as “a direction in which the dimensional difference is the maximum”.

The dimensional difference (B−A) may tend to occur when a plurality of connectors are attached to a single filter main body, for example, a single connector attaching surface. For example, the flatness of the connector attaching surface of the filter main body is ensured by cutting. If a plurality of connectors are to be attached, the flatness of the contact surface between the connector attaching surface and the apparatus casing tends to vary due to variations in the dimensions of the components of the individual connectors.

In a nonparallel state as illustrated in FIG. 11A, the connector follows the apparatus casing when the nut is tightened to cause a force that separates the connector from the filter main body, as illustrated in FIG. 11B. For example, the fastening force of the nut is significantly larger than the fastening force of the connector fastening screws (the total fastening force of the four screws). This causes a force F that separates the connector from the filter main body. This force F acts to separate the connector from the filter main body, as illustrated in FIG. 11B (see Δ in FIG. 11B). This may make the surface contact between the connector flange and the filter main body unstable, causing passive inter modulation.

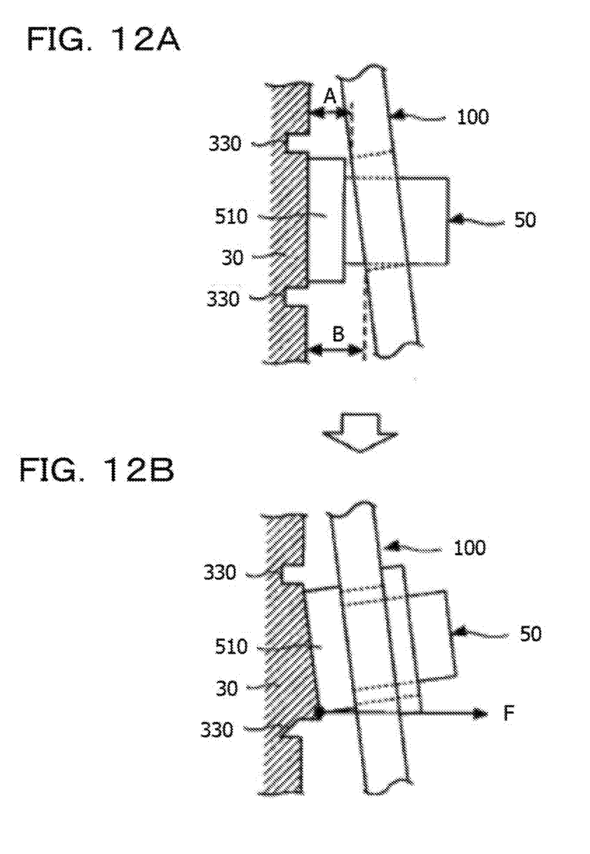

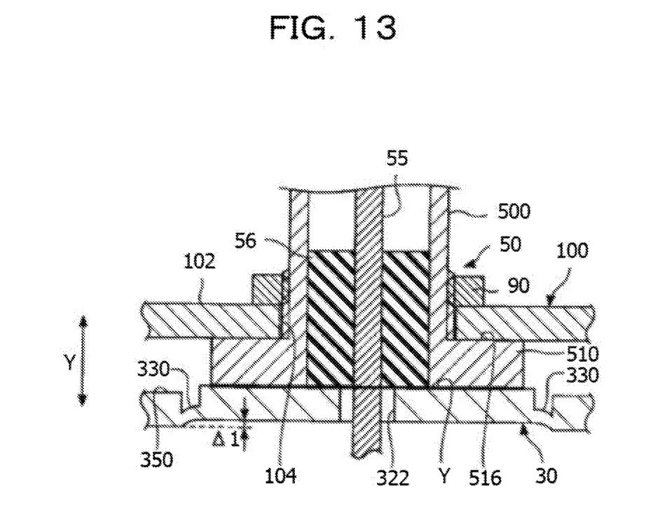

FIGS. 12A and 12B illustrate an example of mounting of a radio communication filtering apparatus. The radio communication filtering apparatus illustrated in FIGS. 12A and 12B may be the radio communication filtering apparatus 1 illustrated in FIG. 2. Like FIGS. 11A and 11B, FIGS. 12A and 12B illustrate attachment of the connector 50 to the apparatus casing 100 in a state in which the connector attaching surface, or the surface 516 of the connector flange 510 (hereinafter similarly typified by “connector attaching surface”), and the contact surface of the apparatus casing 100 are not parallel to each other. FIG. 13 illustrates an example of an apparatus casing to which an apparatus casing connector is attached.

In FIGS. 12A and 12B, the state of contact between the connector flange 510 and the filter main body 30 may not become unstable even if the connector attaching surface and the contact surface of the apparatus casing 100 are not parallel. This may reduce generation of passive inter modulation due to an unstable contact state. For example, as illustrated in FIG. 12B, when the nut 90 is tightened in the radio communication filtering apparatus 1 illustrated in FIG. 2, the connector 50 follows the apparatus casing 100 to cause the force F that separates the connector 50 from the filter main body 30. However, since the filter main body 30 has the grooved portion 330, as described above, the rigidity of the filter main body 30 is lower than that in FIGS. 11A and 11B. This causes the filter main body 30 to be deformed at the grooved portion 330, reducing the force F that separates the connector 50 from the filter main body 30. Thus, in the radio communication filtering apparatus illustrated in FIG. 2, the filter main body 30 is deformed by the grooved portion 330 when the connector 50 is fastened with the nut 90 even if the connector attaching surface and the contact surface of the apparatus casing 100 are not parallel. For example, as illustrated in FIG. 13, the position (parallelism) of the connector attaching portion 320 relative to the peripheral portion 350 is changed due to deformation at the grooved portion 330 according to deviation from the parallelism between the connector attaching surface and the contact surface of the apparatus casing 100. For example, the position of the connector attaching portion 320 relative to the peripheral portion 350 is changed in the plate thickness direction (Y-direction) by a predetermined distance Δ1. This may allow the state of contact between the connector flange 510 and the filter main body 30 to be stably maintained even in a nonparallel state, reducing passive inter modulation due to an unstable contact state. This may make it easy to satisfy exact requirements for passive inter modulation in the radio base station 10. The effect of absorbing the dimensional difference (B−A) (see FIGS. 12A and 12B) due to the fact that the connector attaching surface and the contact surface of the apparatus casing 100 are not parallel using deformation of the grooved portion 330 may be hereinafter referred to as “dimensional-difference absorbing effect using deformation of the grooved portion 330”.

The dimensional-difference absorbing effect using deformation of the grooved portion 330, described above, may relieve allowable tolerance for the flatness of the connector attaching surface of the filter main body 30.

Since the grooved portion 330 encloses the outer periphery of the connector attaching portion 320, the dimensional-difference absorbing effect using deformation of the grooved portion 330 may be given even if the connector attaching surface and the contact surface of the apparatus casing 100 are not parallel. For example, a direction in which the dimensional difference is the maximum when the connector attaching surface and the contact surface of the apparatus casing 100 are not parallel varies according to how the dimensions of the components of the connectors 50 vary. If FIGS. 12A and 12B are diagrams taken in a direction in which the dimensional difference is the maximum, the direction may include any directions in the connector attaching surface, for example, a direction parallel to the Z-direction, a direction parallel to the X-direction, and a direction inclined at any angle to both of the X-direction and the Z-direction. For that reason, if the grooved portion 330 partially encloses the connector attaching portion 320, not all the dimensional difference may be absorbed using deformation of the grooved portion 330, depending on the relationship between a direction in which the dimensional difference is the maximum and the position of the grooved portion 330. For example, if the grooved portion 330 is not formed in a direction in which the dimensional difference is the maximum, not all the dimensional difference may be absorbed using the deformation of the grooved portion 330. For example, since the above-described grooved portion 330 encloses the outer periphery of the connector attaching portion 32, the above problem may be reduced. For example, a grooved portion that partially encloses the outer periphery of the connector attaching portion 320 may be formed instead of the grooved portion 330.

The grooved portion 330 may be easy to form because it is formed on the outer surface of the filter main body 30, as described above. For example, the grooved portion 330 may be formed at casting. For example, the grooved portion 330 may be formed on the inner surface of the filter main body 30.

The plate thickness t2 of the grooved portion 330 may be smaller than the plate thickness t1 of the connector attaching portion 320 and may be equal to or less than half the plate thickness t1 of the connector attaching portion 320. For example, when the basic plate thickness t3 of the peripheral portion 350 of the filter main body 30 is 4 mm, the plate thickness t2 of the grooved portion 330 may be in the range of 0.5 mm to 2 mm. The width w1 of the grooved portion 330 may be in the range of 3 mm to 5 mm. In such a case, the predetermined distance Δ1 illustrated in FIG. 13 is, for example, about 100 μm, thus effectively giving the dimensional-difference absorption effect using deformation of the grooved portion 330. The predetermined distance Δ1 may be determined based on a test value (actual value) of a dimensional difference (B−A) that can arise due to the fact that the connector attaching surface and the contact surface of the apparatus casing 100 are not parallel to each other.

The distance d between the grooved portion 330 and the connector 50 in the connector attaching surface (see FIG. 5) may be 5 mm or less over the entire circumference of the connector 50. This may effectively give the dimensional-difference absorption effect using deformation of the grooved portion 330 even if a direction in which the dimensional difference is the maximum varies.

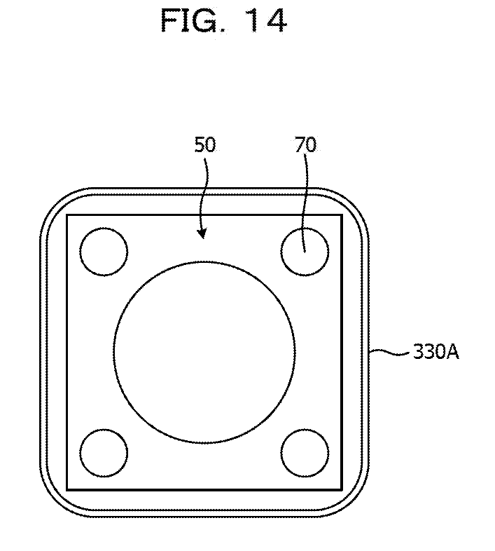

FIGS. 14, 15, and 16 illustrate examples of the shape of the grooved portion 330. There is no restriction on the shape of the grooved portion 330 when viewed in the direction (Y-direction) perpendicular to the connector attaching surface, and the shape may be determined based on the shape of the connector flange 510, ease of processing, etc. (see FIGS. 14 to 16).

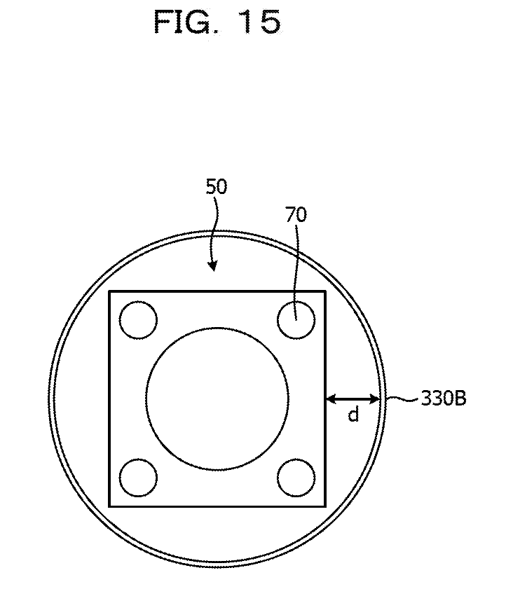

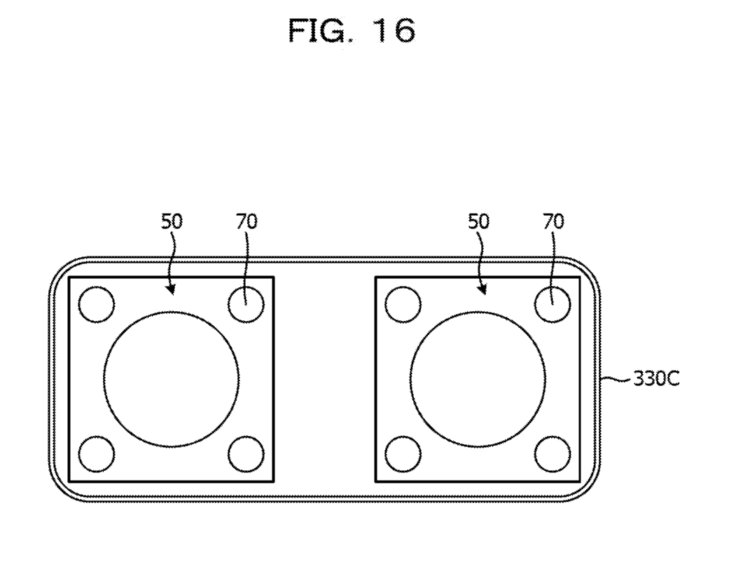

FIG. 14 illustrates the shape of a grooved portion 330A, for example, a plan view when viewed in a direction (Y-direction) perpendicular to the connector attaching surface. FIG. 14 (as well as FIGS. 15 and 16 below) illustrates a simplified shape of the grooved portion.

The grooved portion 330A illustrated in FIG. 14 differs from the above-described grooved portion 330 in that the shape when viewed in the direction perpendicular to the connector attaching surface is a quadrangular shape with rounded corners. For example, the grooved portion 330 has a quadrangular shape with substantially no rounded corners, while the grooved portion 330A illustrated in FIG. 14 is a quadrangular shape with rounded corners. The grooved portion 330A in FIG. 14 may give the same effect as that of the grooved portion 330.

Although the grooved portion 330A illustrated in FIG. 14 has a quadrangular shape with rounded corners, the grooved portion may have another polygonal shape with rounded corners or another polygonal shape with substantially no rounded corners.

FIG. 15 illustrates the shape of a grooved portion 330B, for example, a plan view when viewed in a direction (Y-direction) perpendicular to the connector attaching surface.

The grooved portion 330B differs from the above-described grooved portion 330 in that the shape when viewed in a direction perpendicular to the connector attaching surface is a circular shape. The grooved portion 330B in FIG. 15 may give the same effect as that of the grooved portion 330. When the grooved portion 330B illustrated in FIG. 15 is used, portions where the distance d between the grooved portion 330B in the connector attaching surface and the connector 50 is relatively large are generated. For that reason, the grooved portion 330B illustrated in FIG. 15 may be used in a case where a relatively large connector attaching surface is provided.

The grooved portion 330B illustrated in FIG. 15 may have a shape including an any curve, such as an elliptical shape.

FIG. 16 illustrates the shape of a grooved portion 330C, for example, a plan view when viewed in a direction (Y-direction) perpendicular to the connector attaching surface.

The grooved portion 330C illustrated in FIG. 16 differs from the above-described grooved portion 330 in that the grooved portion 330C encloses a plurality of (two in the example in FIG. 16) connectors 50. The above-described grooved portion 330 has a shape that encloses one connector 50 when viewed in a direction perpendicular to the connector attaching surface, while the grooved portion 330C illustrated in FIG. 16 has a shape that encloses two connectors 50. The grooved portion 330C illustrated in FIG. 16 also gives the same effect as that of the grooved portion 330. When the grooved portion 330C illustrated in FIG. 16 is used, no grooved portion is present between the adjacent two connectors 50. For that reason, when a direction in which the dimensional difference is the maximum passes between the adjacent two connectors 50, dimensional difference may not be sufficiently absorbed using deformation of the grooved portion 330C.

Although the shape of the grooved portion 330C illustrated in FIG. 16 is a quadrangular shape with rounded corners, the grooved portion may have another polygonal shape with rounded corners or another polygonal shape with substantially no rounded corners.

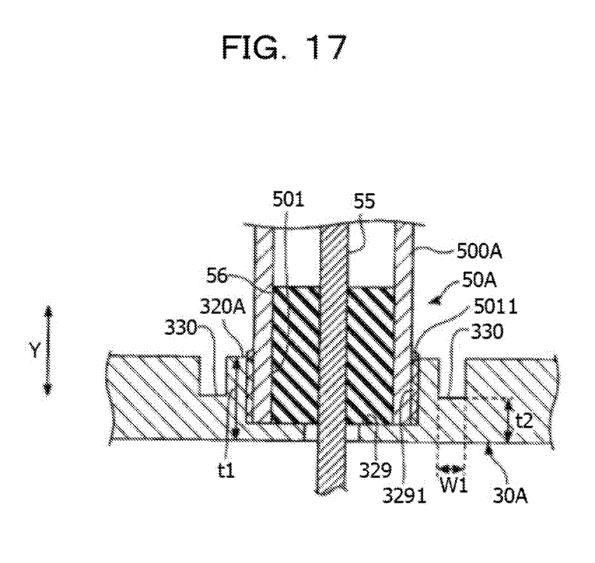

In the radio base station below, the radio communication filtering apparatus 1 of the radio base station 10 may be replaced with a radio communication filtering apparatus 1A. Therefore, descriptions of configurations other than that of the radio communication filtering apparatus 1A will be omitted. The radio communication filtering apparatus 1A differs from the radio communication filtering apparatus 1 according to the first embodiment in that the connector 50 is replaced with a connector 50A and that the filter main body 30 is replaced with a filter main body 30A. Components that may be the same as those of the first embodiment are given the same reference signs in FIG. 17, and descriptions thereof will be omitted.

FIG. 17 illustrates a filter main body 30A and the connector 50A according to a second embodiment.

The filter main body 30A differs from the filter main body 30 in that the connector attaching portion 320 is replaced with a connector attaching portion 320A. The connector attaching portion 320A has a recess 329 in the center. The recess 329 has an internal thread 3291 around the peripheral wall.

The connector 50A differs from the connector 50 in that the connector 50A does not include the connector flange 510 and that the main body 500 is replaced with a main body 500A. The main body 500A has an end 501 having an external thread 5011 around the outer circumference. The end 501 of the connector 50A is fastened in the recess 329 of the connector attaching portion 320A via the internal thread 3291 and the external thread 5011. In other words, the connector 50A is secured to the filter main body 30A by fastening the external thread 5011 of the end 501 to the internal thread 3291 in the recess 329.

The filter main body 30A is secured to the apparatus casing 100 with the nut 90 as in FIGS. 8 and 9.

Also in FIG. 17, the same effect as in the above may be given because the connector attaching portion 320A has the grooved portion 330.

The plate thickness t2 of the grooved portion 330 may be smaller than the maximum plate thickness t1 of the connector attaching portion 320A and may be equal to or less than the maximum plate thickness t1 of the connector attaching portion 320A. The “maximum” plate thickness t1 of the connector attaching portion 320A does not include a plate thickness in the region of the recess 329 in the connector attaching portion 320A. For example, when the basic plate thickness t3 of the peripheral portion 350 of the filter main body 30A is 4 mm, the maximum plate thickness t1 of the connector attaching portion 320A is 8 mm. In this case, the plate thickness t2 of the grooved portion 330 may be in the range of 0.5 mm to 2 mm and the width w1 of the grooved portion 330 may be in the range of 3 mm to 5 mm, as in the above.

The above embodiments are given for mere illustration and may be variously modified and changed. All or a plurality of the components of the above embodiments may be combined.

For example, although the radio base station 10 is illustrated as an example of a radio control apparatus, another radio control apparatus, such as a multiple radio communication apparatus disposed in a site where no optical line can be installed, may be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A radio communication filtering apparatus comprising:
a filter main body including a connector attaching portion and a grooved portion that encloses at least a part of the connector attaching portion; and
a connector to be attached to the connector attaching portion.

2. The radio communication filtering apparatus according to claim 1, wherein the grooved portion is formed on an outer surface of the filter main body.

3. The radio communication filtering apparatus according to claim 1, wherein the grooved portion encloses a periphery of the connector attaching portion.

4. The radio communication filtering apparatus according to claim 1, wherein the filter main body comprises a plurality of sets of the connector attaching portion and the grooved portion.

5. The radio communication filtering apparatus according to claim 1, wherein the grooved portion has a plate thickness equal to or less than half of a maximum plate thickness of the connector attaching portion.

6. The radio communication filtering apparatus according to claim 1,
wherein the connector attaching portion has a maximum plate thickness of 4 mm, and
wherein the grooved portion has a plate thickness in a range of 0.5 mm to 2 mm.

7. The radio communication filtering apparatus according to claim 6, wherein the grooved portion has a width in a range of 3 mm to 5 mm.

8. The radio communication filtering apparatus according to claim 6, wherein a distance between the grooved portion and the connector in an outer surface of the filter main body is equal to or less than 5 mm.

9. The radio communication filtering apparatus according to claim 1, wherein the connector includes a flange that comes into contact with an outer surface of the filter main body and is attached to the filter main body with a screw passing through a hole in the flange.

10. The radio communication filtering apparatus according to claim 1,
wherein the connector has an external thread at an end, and
wherein the connector attaching portion has a recess having an internal thread, and the end of the connector is fastened into the recess.

11. The radio communication filtering apparatus according to claim 1, wherein the filter main body further includes a peripheral portion that encloses the grooved portion and has a plate thickness which is equal to or less than a maximum plate thickness of the connector attaching portion and is larger than a plate thickness of the grooved portion.

12. The radio communication filtering apparatus according to claim 1, wherein the grooved portion has a circular shape, a polygonal shape, or a polygonal shape with rounded corners as viewed in a direction perpendicular to an outer surface of the filter main body.

13. The radio communication filtering apparatus according to claim 1, wherein the connector is fastened to an apparatus casing of a radio control apparatus using a fastener.

14. A radio control apparatus comprising:
an apparatus casing including a through hole;
a filter main body disposed in the apparatus casing and including a connector attaching portion and a grooved portion that encloses at least part of the connector attaching portion;
a connector to be attached to the connector attaching portion and being exposed outside the apparatus casing through the through hole; and
a fastener that fastens the apparatus casing and the connector to each other.

15. The radio control apparatus according to claim 14, wherein the grooved portion is formed on an outer surface of the filter main body.

16. The radio control apparatus according to claim 14, wherein the filter main body comprises a plurality of sets of the connector attaching portion and the grooved portion.

17. The radio control apparatus according to claim 14, wherein the grooved portion has a plate thickness equal to or less than half of a maximum plate thickness of the connector attaching portion.

18. The radio control apparatus according to claim 14, wherein the connector includes a flange that comes into contact with an outer surface of the filter main body and is attached to the filter main body with a screw passing through a hole in the flange.

19. The radio control apparatus according to claim 14,
wherein the connector has an external thread at an end, and
wherein the connector attaching portion has a recess having an internal thread, and the end of the connector is fastened into the recess.

20. The radio control apparatus according to claim 14, wherein the grooved portion has a circular shape, a polygonal shape, or a polygonal shape with rounded corners as viewed in a direction perpendicular to an outer surface of the filter main body.
